(19) United States
(12) Patent Application Publication
(10) Pub. No.: US 2006/0250782 A1
(43) Pub. Date: Nov. 9, 2006

(54) Packaging process and structure of electronic device

(75) Inventors: Choo Soo Lim, Samutprakarn (TH); Phumchai Chaisri, Samutprakarn (TH)

Correspondence Address: MADSON & AUSTIN;GATEWAY TOWER WEST, SUITE 900, 15 WEST SOUTH TEMPLE, SALT LAKE CITY, UT, 84101, US

(73) Assignees: Delta Electronics, Inc.; Delta Electronics (Thailand) Public Company, Limited

(21) Appl. No.: 11/124,975

(22) Filed: May 9, 2005

(51) Int. Cl. H05K 5/00

(52) U.S. Cl. 361/816; 361/752; 361/757

(57) ABSTRACT

A packaging process of an electronic device includes the following steps. Firstly, in step (a), an upper shielding casing, a lower shielding casing and a printed circuit board are provided, wherein the printed circuit board is mounted thereon an input device and an output device. Then, in step (b), the printed circuit board is placed within a closed space defined between the upper shielding casing and the lower shielding casing. Afterward, in step (c), the upper shielding casing and the lower shielding casing are encapsulated with an encapsulation layer and portions of the input device and output device are exposed.

### FIELD OF THE INVENTION

The present invention relates to a packaging process and a packaging structure of an electronic device, and more particularly to a packaging process and a packaging structure of an electronic device, which are advantageous for reinforcing the electronic device, simplifying the fabricating process and increasing productivity and product reliability.

### BACKGROUND OF THE INVENTION

Electronic devices such as adapters and chargers are widely used in the modern society. For example, by means of the adapter, the commercial power supply is rectified and then converted into DC power so as to be directly used in electronic appliances such as notebooks or charged into the rechargeable batteries of the electronic appliances. The housings of the adapters and chargers are jointed together by using ultrasonic welding technologies or fastening screws with nuts. As known, the fastening (screwing) method is very troublesome because many screws with nuts are successively fastened. The ultrasonic welding technology has some drawbacks, which will be described later.

Referring to FIG. 1, a schematic exploded view of a conventional adapter is illustrated. The adapter 1 comprises an upper housing 11, a lower housing 12, a printed circuit board 13, an input device 14 and an output device 15. The input device 14 and the output device 15 are mounted on the printed circuit board 13. A closed space is defined between the upper housing 11 and the lower housing 12 for accommodating therein the printed circuit board 13. By using the ultrasonic welding technology, the contact regions of the upper housing 11 and the lower housing 12 are molten. After the molten material is cooled, the upper housing 11 and the lower housing 12 are jointed together, thereby implementing the assembly of the adapter 1.

For a purpose of enhancing adhesion, the ribs and notches on the connection regions between the upper housing 11 and the lower housing 12 should be aligned with each other before the ultrasonic welding process is performed. Therefore, the ultrasonic welding technology is complicated and very time-consuming.

Since the upper housing 11 and the lower housing 12 are jointed together at a limited contact area, the mechanical strength of the adapter 1 is insufficient. Therefore, the upper housing 11 and the lower housing 12 are easily loosened or fallen off when an external force or a deflection force is exerted.

### SUMMARY OF THE INVENTION

It is an object of the present invention to provide a packaging process and a packaging structure of an electronic device, which are advantageous for reinforcing the electronic device, simplifying the fabricating process and increasing productivity and product reliability.

In accordance with a first aspect of the present invention, there is provided a packaging process of an electronic device. Firstly, in step (a), an upper shielding casing, a lower shielding casing and a printed circuit board are provided, wherein the printed circuit board is mounted thereon an input device and an output device. Then, in step (b), the printed circuit board is placed within a closed space defined between the upper shielding casing and the lower shielding casing. Afterward, in step (c), the upper shielding casing and the lower shielding casing are encapsulated with an encapsulation layer and portions of the input device and the output device are exposed.

Preferably, the electronic device is an adapter or a charger.

In an embodiment, the step (c) is performed by an injection molding process.

In an embodiment, the step (b) further comprises steps of (b1) placing the printed circuit board in a receptacle of the lower shielding casing, and (b2) assembling the upper shield casing and the lower shielding casing together by fastening a pair of first fastening elements of the upper shielding casing with a pair of second fastening elements of the lower shielding casing so as to define the closed space for accommodating therein the printed circuit board.

Preferably, each of the upper shielding casing and the lower shielding casing is made of a high melting point material such as metallic material or polymeric material.

Preferably, the encapsulation layer is made of a high heat-flow material for the injection molding process such as resin or plastic material.

In accordance with a second aspect of the present invention, there is provided a packaging structure of an electronic device. The packaging structure comprises an upper shielding casing and a lower shielding casing defining a closed space therebetween, a printed circuit board mounted thereon an input device and an output device and disposed within the closed space, and an encapsulation layer covering the upper shielding casing and the lower shielding casing and allowing portions of the input device and the output device to be exposed.

In an embodiment, the upper shielding casing has a pair of first fastening elements, and the lower shielding casing has a pair of second fastening elements for fastening with the first fastening elements of the upper shielding casing.

Preferably, the pair of first fastening elements are disposed at the edges of two opposite sides of the upper shielding casing, and the pair of second fastening elements are disposed at the edges of two opposite sides of the lower shielding casing.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic exploded view of a conventional adapter;

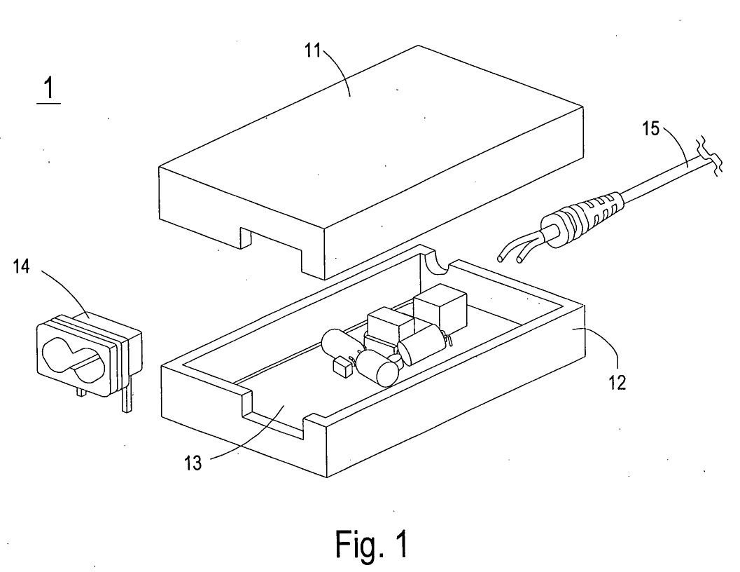

FIG. 2 is a schematic cross-sectional view illustrating a packaging structure of an electronic device according to a preferred embodiment of the present invention;

FIG. 3 is an exploded view illustrating the packaging structure of the electronic device according to the preferred embodiment of the present invention; and

FIG. 4 is a flowchart illustrating a packaging process of the electronic device of the present invention.

### DETAILED DESCRIPTION OF THE PREFERRED EMBODIMENT

The present invention will now be described more specifically with reference to the following embodiments. It is to be noted that the following descriptions of the preferred embodiments of this invention are presented herein for purpose of illustration and description only. It is not intended to be exhaustive or to be limited to the precise form disclosed.

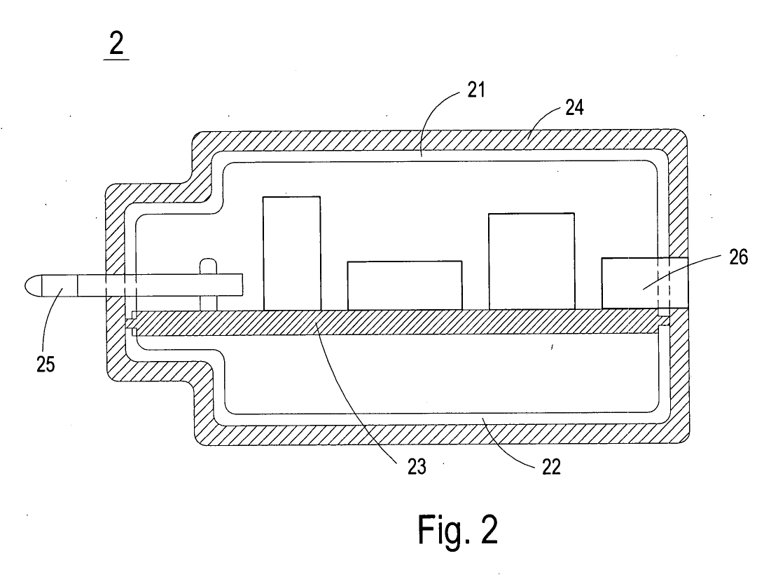

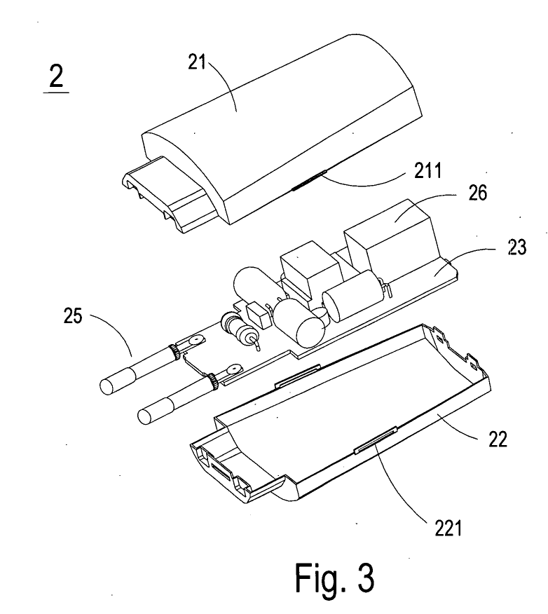

Please refer to FIGS. 2 and 3, which are respectively schematic cross-section view and exploded view illustrating a packaging structure of an electronic device according to a preferred embodiment of the present invention. The electronic device 2 comprises an upper shielding casing 21, a lower shielding casing 22, a printed circuit board 23, an encapsulation layer 24, an input device 25 and an output device 26. The upper shielding casing 21 has a pair of first fastening elements 211 extending outwardly from the edges of two opposite sides. The lower shielding casing 22 has a pair of second fastening elements 221 extending outwardly from the edges of two opposite sides for fastening with the first fastening elements 211 of the upper shielding casing 21. A closed space is defined between the upper shielding casing 21 and the lower shielding casing 22 for accommodating therein the printed circuit board 23. The input device 25 (such as a pair of sleeve pins) and the outputting device 26 (such as a direct current jack) are respectively mounted on and coupled with the printed circuit board 23 at two opposite ends. The encapsulation layer 24 encapsulates the assembly of the upper shielding casing 21 and the lower shielding casing 22 and allows portions of the input device 25 and the output device 26 to be exposed.

The upper shielding casing 21 and the lower shielding casing 22 are made of high melting point materials such as metallic or polymeric materials. The upper shielding casing 21 and the lower shielding casing 22 are highly stable shielding casings for withstanding over-molding resin temperature and pressure. The metallic materials facilitate reducing the electromagnetic interference (EMI), and increasing the efficiency of heat dissipation so as to provide homogenous temperature distribution of the overall electronic device. The outer surfaces of the upper shielding casing 21 and the lower shielding casing 22 are encapsulated with the encapsulation layer 24 for enhancing the mechanical strength of the electronic device. In order to perform the injection molding process, the encapsulation layer 24 is made of a heat-flow material such as resin, plastic material or the like.

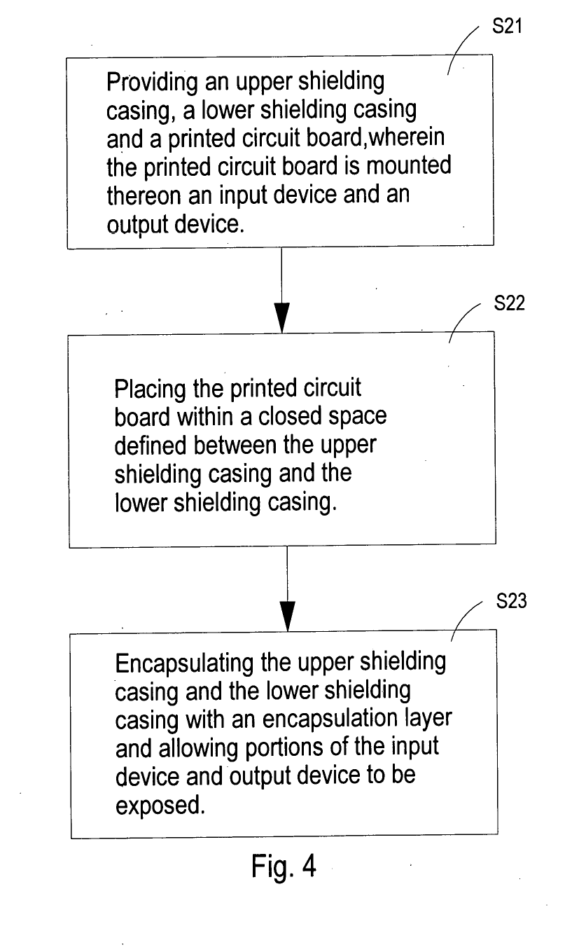

Hereinafter, a packaging process of the electronic device of FIGS. 2 and 3 will be illustrated with reference to FIG. 4.

In step S21, an upper shielding casing 21, a lower shielding casing 22 and a printed circuit board 23 are provided. The printed circuit board 23 is mounted thereon an input device 25 and an output device 26 as shown in FIG. 3.

Subsequently, in step S22, the printed circuit board 23 is disposed within the closed space defined between the upper shielding casing 21 and the lower shielding casing 22. In some embodiments, the printed circuit board 23 is firstly placed in the receptacle of the lower shielding casing 22, and then the upper shield casing 21 and the lower shielding casing 22 are assembled together by fastening the first fastening elements 211 of the upper shielding casing 21 with the second fastening elements 221 of the lower shielding casing 22, thereby defining the closed space for accommodating therein the printed circuit board 23.

Subsequently, in step S23, by an injection molding technology, the outer surfaces of the upper shielding casing 21 and the lower shielding casing 22 are encapsulated with the encapsulation layer 24 and portions of the input device 25 and the output device 26 are exposed, thereby completing the packaging process.

The packaging structure and process of the present invention can be applied to an adapter, a power supply or a charger. It is noted that, however, those skilled in the art will readily observe that numerous modifications and alterations of the connection member may be made while retaining the teachings of the invention. For example, the input element 25 can be a socket and the output element 26 can be a power cord. Accordingly, the above disclosure should be limited only by the bounds of the following claims.

As previously described, the ultrasonic welding technology for packaging the electronic device is complicated and very time-consuming because the ribs and notches on the connection regions between the upper housing 11 and the lower housing 12 should be aligned with each other before the ultrasonic welding process is performed. Since the electronic device of the present invention is packaged by encapsulating two shielding casings with the encapsulation layer according to the injection molding technology, the mechanical strength of the package structure is largely increased without the need of precise alignment. Furthermore, the fabricating process of the present invention is simplified when compared with the ultrasonic welding technology. Therefore, the productivity and product reliability are enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A packaging process of an electronic device, comprising steps of:
(a) providing an upper shielding casing, a lower shielding casing and a printed circuit board, wherein said printed circuit board is mounted thereon an input device and an output device;
(b) placing said printed circuit board within a closed space defined between said upper shielding casing and said lower shielding casing; and
(c) encapsulating said upper shielding casing and said lower shielding casing with an encapsulation layer and exposing portions of the said input device and said output device.

2. The packaging process according to claim 1 wherein said electronic device is selected from a group consisting of an adapter and a charger.

3. The packaging process according to claim 1 wherein said step (c) is performed by an injection molding process.

4. The packaging process according to claim 1 wherein said step (b) comprises steps of:
(b1) placing said printed circuit board in a receptacle of said lower shielding casing; and
(b2) assembling said upper shield casing and said lower shielding casing together by fastening a pair of first fastening elements of said upper shielding casing with a pair of second fastening elements of said lower shielding casing so as to define said closed space for accommodating therein said printed circuit board.

5. The packaging process according to claim 1 wherein each of said upper shielding casing and said lower shielding casing is made of metallic material or polymeric material.

6. The packaging process according to claim 1 wherein said encapsulation layer is made of resin or plastic material.

7. A packaging structure of an electronic device, comprising:
an upper shielding casing and a lower shielding casing defining a closed space therebetween;
a printed circuit board mounted thereon an input device and an output device and disposed within said closed space; and
an encapsulation layer covering said upper shielding casing and said lower shielding casing and allowing portions of said input device and said output device to be exposed.

8. The packaging structure according to claim 7 wherein said upper shielding casing has a pair of first fastening elements, and said lower shielding casing has a pair of second fastening elements for fastening with said first fastening elements of said upper shielding casing.

9. The packaging structure according to claim 8 wherein said pair of first fastening elements are disposed at the edges of two opposite sides of said upper shielding casing, and said pair of second fastening elements are disposed at the edges of two opposite sides of said lower shielding casing.

10. The packaging structure according to claim 7 wherein said electronic device is selected from a group consisting of an adapter and a charger.

11. The packaging structure according to claim 7 wherein said encapsulation layer is formed by an injection molding process.

12. The packaging structure according to claim 11 wherein said encapsulation layer is made of resin or plastic material.

13. The packaging structure according to claim 7 wherein each of said upper shielding casing and said lower shielding casing is made of metallic material or polymeric material.
